(19) United States
(12) Patent Application Publication
(10) Pub. No.: US 2005/0180223 A1
(43) Pub. Date: Aug. 18, 2005

(54) Accessing stored data

(76) Inventors: Guy de Warrenne Bruce Adams, Stroud (GB); Charles E. Schinner, Windsor, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/103,496

(22) Filed: Apr. 12, 2005

Related U.S. Application Data
(62) Division of application No. 10/284,446, filed on Oct. 31, 2002.

(51) Int. Cl. G11C 5/00

(52) U.S. Cl. 365/189.05

(57) ABSTRACT

A user interface device adapted to access at least one data item stored in an electronic data storage device has at least one actuating region for actuating a switch, and a surface portion having a mark printed thereon in a predetermined positional relationship with the actuating region, the mark being associated with a respective data item. The interface device is connectable with the data storage device and adapted to access data stored on the data storage device and to initiate communication with at least one user access device, to transmit a data item to the user access device. A method of operating the interface device includes associating user-operable switch actuating regions of the interface device with data items stored in a data storage device.

### BACKGROUND OF THE INVENTION

1. Field of the Invention

The invention relates generally to the field of devices for accessing stored data, and to blanks, methods and apparatus for use in producing such devices.

2. Description of the Related Art

Electronic storage devices are presently used to store data in a form that is not readily accessible to humans. For example, data items may be stored in the form of data files relating to respective records in the form of digital images, video, audio, or audiovisual clips. In order to access such records, the data items are generally loaded onto an access device. For example, a storage device, such as a memory card, may be inserted into a memory card reader of an access device, such as a printer device or personal computer (PC), for displaying and/or printing images stored as data items on the card. In general, each access device must be provided with a respective user interface for user selection of desired records, and a respective reader for reading data from the storage device. Also, a storage device must first be inserted in an access device before a user can review what content is stored on the storage device and available for selection by the user.

### SUMMARY OF THE INVENTION

According to a first aspect of the invention, there is provided a user interface device, for use in accessing at least one data item stored on an electronic data storage device, comprising:
at least one actuating region for actuating a respective switch; and
a surface portion having printed thereon, in predetermined positional relationship with at least one said actuating region, at least one mark associated with a respective said data item;
said interface device being:
connectable with the data storage device, for accessing data stored on said data storage device; and
operable to initiate communication with at least one user access device, for causing said data item to be transmitted to said user access device.

In accordance with a further aspect of the invention, there is provided an interface device, for use in accessing media records stored as data items on a storage device, comprising: a plurality of switches; a plurality of corresponding switch actuating regions; images corresponding to said data items, respectively printed over said actuating regions; a controller for controlling the interface; a path arrangement operably connecting at least one of said plurality of switches with said controller; connector apparatus for removably connecting said interface device with said storage device; and transceiver apparatus for data communication with an access device; whereby a user can use said images to select a corresponding said data item and actuate one of said switches to cause an access device to process the selected data item.

In accordance with a still further aspect of the invention, there is provided a user interface device having: connectivity to a non-volatile memory device, user input functionality enabling a user to identify and select records stored as data items on said memory device, and output functionality for transferring selected said data items to a remote access device.

Thus, easy and simple user selection is facilitated of data items that are not stored in human readable or audible form, for human-perceptible access to the data items using the interface device in conjunction with an access device.

In accordance with further aspects of the invention, there is provided blanks for production of the interface device.

In accordance with a yet further aspect of the invention, there is provided a method for associating user-operable switch actuating regions of an interface device with data items stored on a data storage device, comprising:
receiving information from a data storage device relating to at least one data item stored on the data storage device;
using said information to generate a mark representing a respective data item; and
using information about a disposition of at least one of said actuating regions so as to:
logically associate at least one stored data item with at least one respective switch actuating region; and
place at least one of said marks in an arrangement in which at least one of said marks is aligned with at least one said switch actuating regions that is operable for accessing a data item corresponding to the mark.

Production of a customized interface device is thus facilitated, using information relating to stored data items, for interaction with a storage device on which the data items are stored. This facilitates provision of interfaces that are more intuitive to use, since tailored for use with a particular type of data item and/or for a user's special preferences.

The user interface device may be provided with a support adapted to receive a said storage device, whereby said interface device can be used to carry said storage device, and the support may arranged so as to align said received storage device with said interface device, in use, for facilitating correct connection therebetween. Physical storage of the electronic data storage device with an associated customized user interface device is thereby facilitated. Such storage should become more attractive to users, for example, for archiving purposes, as the prices of storage devices drop and users no longer perceive a need to reuse them

### BRIEF DESCRIPTION OF THE DRAWINGS

In order that the invention may be well understood, various embodiments thereof will now be described, by way of example only, with reference to the accompanying drawings, in which:

FIG. 1 is a schematic view from one side of an interface device;

FIG. 2 is a schematic view in partial section from an opposite side of the interface device;

FIG. 3 is a schematic view in partial section from an opposite side of a modified interface device;

FIG. 4 is an exploded schematic view of a specially adapted memory card for use with a modified interface device;

FIG. 5 is a schematic view from a side of an interface device similar to that in FIG. 1, showing modifications to the interface device;

FIG. 6 is a flowchart of a method of producing an interface device;

FIG. 7 is a flowchart of a method for associating record marks with stored data items;

FIG. 8 is a schematic drawing showing the use of a printing device and an interface device blank in a method according to FIG. 6;

FIG. 9 is a flowchart of an alternative method of producing an interface device;

FIG. 10 is a schematic drawing showing the use of a printing device and an interface device blank in a method according to FIG. 9;

FIG. 11 is a flowchart of a further alternative method of producing an interface device;

FIG. 12 is a schematic drawing showing the use of computer apparatus, a printing device and an interface device blank in a method according to FIG. 11; and

FIG. 13 is an exploded view of a printed overlay and an interface device blank having alignment marks for aligning the overlay.

### DETAILED DESCRIPTION OF THE DRAWINGS

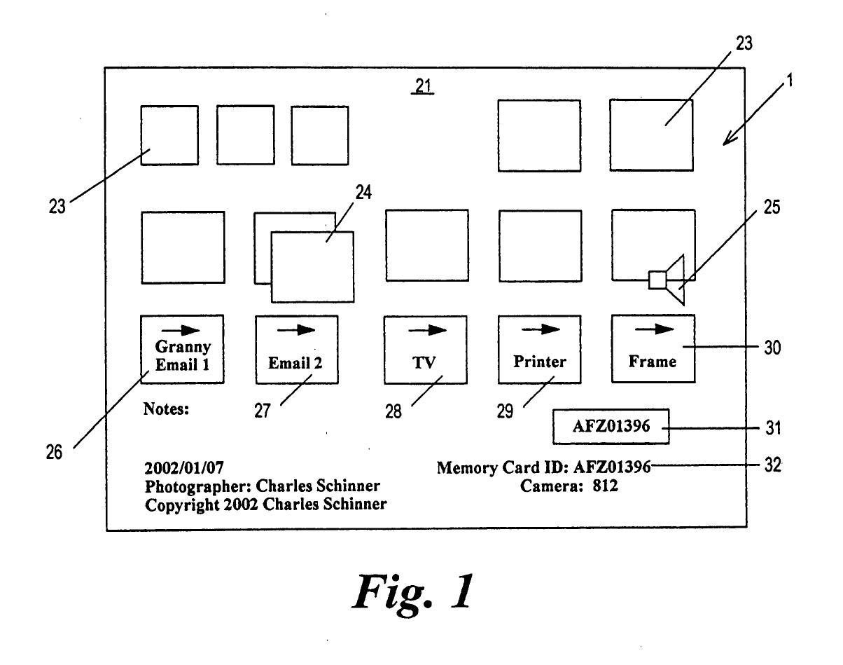

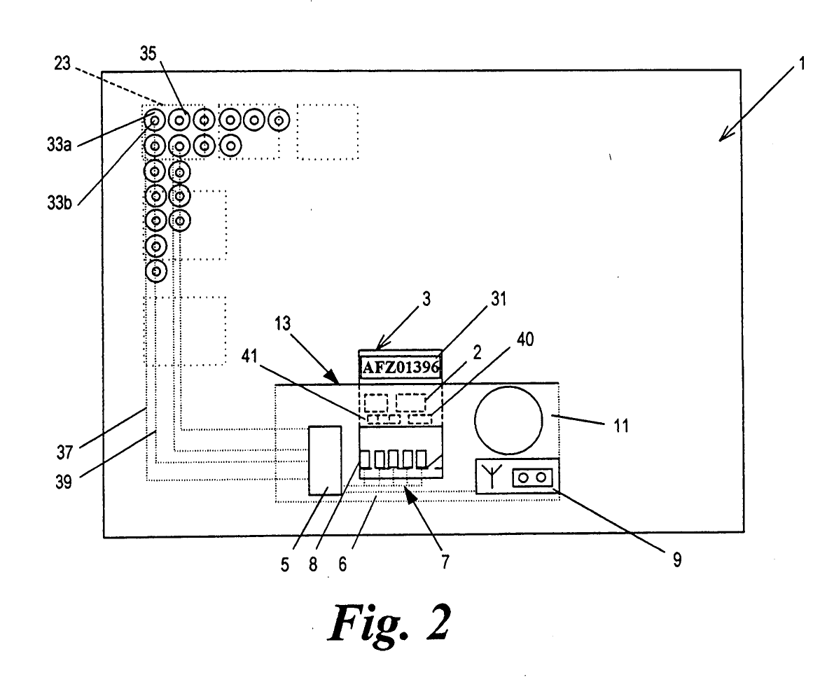

FIGS. 1 and 2 show a user interface device 1 for use in accessing at least one data item 2 stored on an electronic data storage device in the form of a memory device 3. The memory device 3 is shown in the form of a memory card, but may alternatively be any other suitable non-volatile memory device. It is desirable that the memory device 3 is light and small enough to be carried by a person with relative ease. The data items 2 are records, for example, photographic or video images, audio or audiovisual clips, or other rich media records, encoded in digital form. It will be understood that although the data items 2 are shown as discrete items, each can be distributed across the non-volatile memory of the memory card 3 in any convenient manner.

As best seen in FIG. 2, the interface device 1 has a controller 5 in the form of an integrated circuit for controlling the interface device 1 and the memory card 3. The controller 5 is connected, for example, using embedded conductive tracks 6 or a circuit board, to connector apparatus 7. The connector apparatus 7 has electrically conductive contacts adapted to engage associated contacts of a connector 8 on the memory card 3, for making a physical connection between the controller 5 and the memory card 3. A power source 11 in the form of a battery, for example, is connected for providing power to the interface device 1 and the memory card 3. A wireless module in the form of a wireless and/or infrared transceiver 9 is connected to the controller 5, for communicating with a remote access device (not shown). The term wireless means any form of connection without wires, and includes radio frequency (RF) and infrared communication technologies. The access device with which the transceiver 9 is capable of communicating could, for example, be a printer, personal computer or personal digital assistant, a display device, such as a television, or any other suitable access device.

A support in the form of a pocket 13 is adapted to receive the memory card 3 such that an end portion 4 of the memory card 3 protrudes from the pocket 13. The pocket 13 serves to align the memory card 3 with the contacts 7 during insertion of the memory card 3 into the pocket 13, and to retain the memory card 3 securely together with the interface device 1 for convenient carriage and storage of the card 3 using the interface device 1. Further, alternative arrangements of the memory card 3 relative to the pocket 13 will be apparent to the skilled reader. For example, in one alternative embodiment, the memory card 3 is contained substantially entirely within the pocket 13 and does not protrude from the pocket 13.

An identification number, indicated by reference sign 32, is permanently marked on the front face of the interface device 1. A self-adhesive label 31 bearing the same identification number is also initially provided on the interface device 1. The label 31 is arranged for easy removal from the interface device 1 for application to the protruding portion 4 of the memory card 3 as shown in FIG. 2. Thus, the interface device 1 can be easily rematched with a corresponding memory card 3 using the identification number if the device 1 and card 3 become separated.

As best seen in FIG. 1, the interface device 1 comprises a surface portion 21. The surface portion 21 is formed by a face of the body of the interface device 1, but can alternatively be provided by a printed sheet subsequently attached to the body. The surface portion 21 carries printed marks 23 to 25 in the form of compact visual representations corresponding to the respective records stored as data items 2. These record marks 23 to 25 can all be of the same size and type. Alternatively, the record marks 23 to 25 can vary in size and/or type, for example, in accordance with the type of record represented, as shown in FIG. 1. For example, record marks are shown in FIG. 1 in the form of i) thumbnail marks 23 of various sizes representing still images, ii) overlapping marks 24 representing a video clip record and iii) a thumbnail mark 25 with a speaker symbol representing a still image with audio clip.

The term thumbnail as used herein means a lower resolution pictorial image derived from a higher resolution image. However, the record marks 23 to 25 need not be thumbnails, and could alternatively, for example, take the form of descriptive words, iconic images that are associated with a data item 2 but not generated directly from the data item 2, filenames, or any other convenient descriptor. The record marks 23, 24, 25 are usable in the manner of an index card, for user identification and selection of records that are encoded as data items 2 on the memory card 3.

As also seen in FIG. 1, further marks 26 to 30 are printed on the surface portion 21, corresponding to respective destinations to which the data items 2 may be transmitted by the interface device 1. For example, the destination marks 26 and 27 relate to a computer device having an e-mail client program, and further specify particular addresses for use by the e-mail client. The destination marks 28 to 30 relate to a television apparatus, printer apparatus and frame (display and storage) apparatus respectively.

As shown in FIG. 2, an array of switches is provided in an area of the interface device 1 beneath the surface portion 21 on which the marks 23 to 30 are printed. The switches in FIG. 1 are formed by conductive contacts 33a, 33b on respective opposed inner surfaces formed by laminations of the interface device 1. The laminations are arranged such that the contacts 33a, 33b are resiliently biased towards a “switch open” position in which the contacts 33a, 33b do not interengage. A switch is closed by applying pressure to an actuating region 35 of the surface portion 21 to overcome the bias and press the contacts 33a, 33b of the switch together. The size and shape of an actuating region 35 can vary depending on the size and design characteristics of the switch 33a, 33b. In FIG. 2, the size of each actuating region 35 is coterminous with an outer peripheral extent of its corresponding switch 33a, 33b. In order to simplify the drawings, not all of the switches 33a, 33b are shown.

Each switch 33a, 33b is operably connected to the controller 5 by respective paths 37, 39 in the form of electrically conductive tracks formed by conductive wires embedded in the body of the interface device. Paths 37 form a common connection with the contacts 33a. Each of the paths 39 is connected to one respective contact 33b. When a pair of contacts 33a and 33b is brought together, the path 39 is thus grounded, and the switch 33a, 33b is thus activated. In order to simplify the drawings, not all of the paths 37, 39 are shown. Many alternative ways of arranging the paths 37, 39 will be apparent to the skilled reader. For example, in one alternative arrangement a grid of paths aligned with mutually perpendicular (X-Y) axes is formed. The X and Y paths are arranged on spaced, oppositely and inwardly facing surfaces of respective laminations. Regions of an outer surface of one of the laminations may be pressed by a user so as to bring horizontal and vertical paths into contact where they cross in the grid. A sequencer is provided to scan the paths to sense locations of crossed paths (switches) in the grid that have been activated.

Whilst the paths 37, 39 comprise embedded wires, many alternative ways of forming the paths will be readily apparent to the skilled reader. For example, the paths 37, 39 can be formed by any of the following processes: embossing by transferring previously prepared tracks to the interface device under pressure from a carrier; transferring previously prepared tracks from a carrier and adhering the tracks to the interface device; direct printing of conductive material onto the interface device so as to form tracks, using a printer adapted for this purpose; or any other convenient method. Optical waveguides could alternatively be used instead of the conductive tracks to transmit signals from the switches 33a, 33b to the controller 5, or any suitable further alternative means of transmission.

A mapping 40 in the form of a look-up table, or file containing associations, is stored in non-volatile memory accessible to the controller 5. For example, the mapping 40 could be stored in the memory card 3 as shown in FIG. 2, or alternatively in the controller integrated circuit 5 or elsewhere on the interface device 1. For each record mark 23 to 25, the mapping 40 provides a logical association between at least one corresponding switch 33a, 33b and an associated stored data item 2. Thus, the controller 5, on receiving a signal from an actuated record mark switch 33a, 33b, identifies a corresponding location in the memory card's non-volatile memory, for accessing a data item 2 stored in the identified location. The record marks 23 to 25 and the mapping 40 are mutually arranged such that the data item 2, identified using the mapping 40, is related to the printed record mark 23 to 25 aligned with the actuating region 35 of the actuated switch 33a, 33b. Thus, a user desirous of selecting a particular record for access can use the marks 23 to 25 to actuate an appropriate switch 33a, 33b so as to cause the interface device 1 to access the data item 2 related to the desired record.

Each record mark 23, 24, 25 is aligned with a respective plurality, or group, of actuating regions 35 corresponding to a plurality of respective switches 33a, 33b. Providing a grid of many smaller switches 33a, 33b allows the user more flexibility in selecting the size and disposition of the marks 23 to 30 when producing a customized interface device 1.

For each destination mark 26 to 30, the mapping 40 provides a logical association between at least one corresponding switch 33a, 33b and respective stored computer instructions 41. The computer instructions 41 are conveniently stored in the memory card 3 as shown in FIG. 2, but at least some of the computer instructions 41 could alternatively be stored elsewhere and/or include short cuts to instructions stored elsewhere. Thus, the controller 5, on receiving a signal from an actuated destination mark switch 33a, 33b, identifies a corresponding location in the memory card's non-volatile memory, for accessing computer instructions 41 stored in the identified location. The destination marks 26 to 30 and the mapping are mutually arranged such that the identified computer instructions 41 correspond to an access device represented by the destination mark 26 to 30 aligned with the actuating region 35 of the actuated switch. Thus, a user desirous of selecting a particular access device for accessing a selected data item 2 can use the destination marks 26 to 30 to actuate an appropriate switch 33a, 33b so as to cause the interface device 1 to access and execute computer instructions 41 related to a desired access device.

The computer instructions 41 are adapted to execute so as to cause the controller 5, using transceiver 9, to effect communication with the corresponding access device and transmission to the access device of any presently selected data item or items 2. The computer instructions 41 also cause the controller 5 to call up any necessary further computer instructions that are needed to effect the communication and transmission. For example, a program may be called to pack data items for transmission in accordance with an appropriate communications protocol, and/or a printer driver or specific printer control language instructions may be called. Additionally or alternatively, a predetermined e-mail address or broadcast address list may be called.

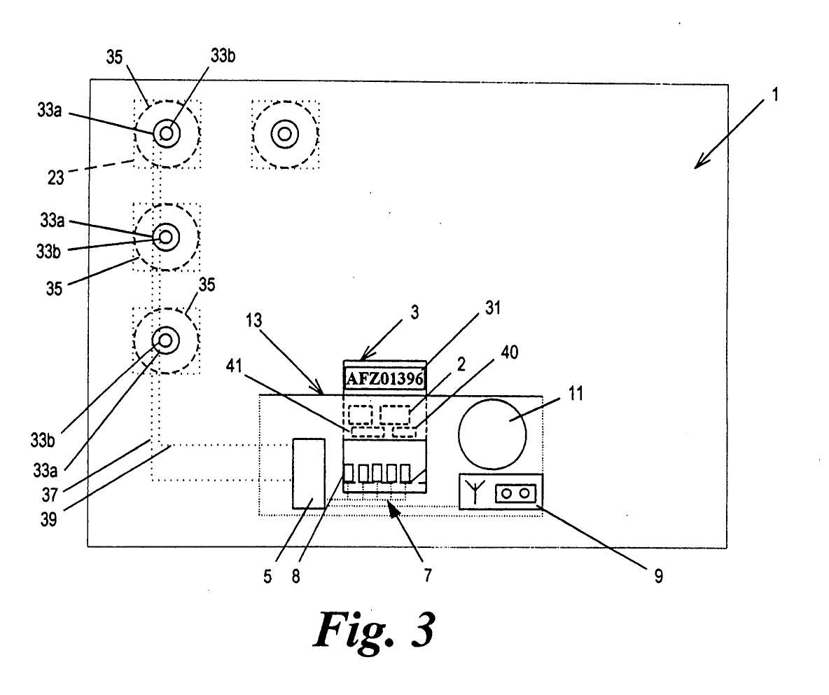

A modified embodiment of the interface device 1 is shown in FIG. 3, wherein like reference signs are used to designate features already described above with reference to FIGS. 1 and 2. To avoid unnecessary repetition such features are not described again in detail.

In FIG. 3, the switches 33a, 33b are larger than in the embodiment of FIG. 2, and the actuating regions 35 extend radially outwardly of the outermost periphery of the switches 33a, 33b. One switch 33a, 33b, and thus one actuating region 35, is aligned under each mark 23. It will be understood that any other convenient size of actuating region could alternatively be provided.

Alternative suitable forms of switch will be readily apparent to the skilled man. For example, pressure or touch sensing elements or switches could be incorporated within the interface device 1. Each switch and its actuating region can in this case be integral with one another. The interface device may be provided with a specially adapted surface portion 21 if necessary for facilitating pressure or touch sensing. For example, capacitive touch sensing may require an electrically conductive surface. In another alternative form, the switches are printed inductive coils and require a specially adapted wand for actuation.

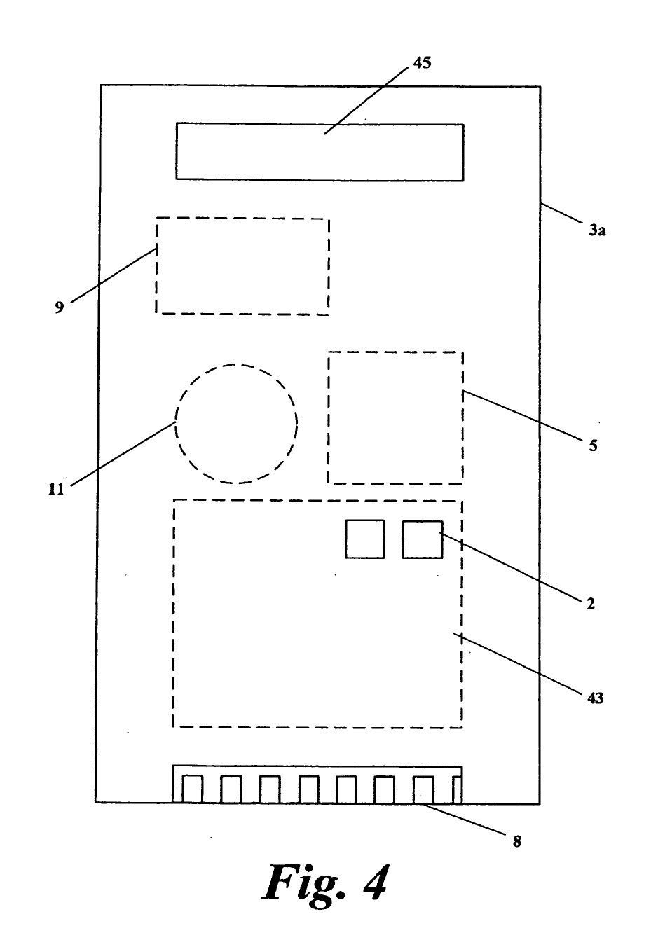

In a further modified interface device 1 (not shown), the functions of at least one of the controller 5, wireless module 9 and battery 11 are provided by the memory device, and the interface device 1 omits the controller 5, module 9 and/or battery 11 as the case may be. A memory card 3a specially adapted for this purpose is shown in FIG. 4. The memory card 3a includes the remote transceiver 9, power source 11 and controller 5, connected for communication with the interface device 1 by means of a mechanical connector 8. Instead of the connector 8, a wireless connection can be provided by the transceiver 9 or a dedicated further transceiver. The memory card 3a also includes storage locations 43 in non-volatile memory for storing data such as respective data items 2 and computer instructions 41, and a location 45 on its surface for receiving the identification label 31.

The memory card 3a is operable to receive signals from switches 33a, 33b of the interface device 1, to process the signals and, in response to the signals, to supply data items 2 and computer instructions 41 from the storage locations 43 for processing by an access device. The memory card 3a can supply data items 2 direct to an access device using the transceiver 9. However, if the transceiver were alternatively part of the interface device 1, the memory card would supply the data items 2 and computer instructions 41 to the interface device for onward transmission to an access device.

In use, a user views the printed index of record marks 23 to 25 to review the contents of the memory card 3 stored with the interface device 1. Thus, the user can conveniently sort through many memory cards 3 to identify those in which he may be interested, without having to connect the memory cards 3 to an access device. For example, the user selects a photographic image by pressing on a thumbnail mark 23 of that image. The thumbnail mark 23 is disposed in a switch actuating region 35, so that the pressing action causes activation of a corresponding switch 33a, 33b. The switch generates a signal to the controller 5. The controller uses the mapping 40 to identify a memory location where there is stored a data item 2 corresponding to the selected photographic image.

The user decides that he wishes to send the image to his grandmother. He presses a destination mark “Granny e-mail” 26. The destination mark 26 is disposed in an actuating region 35, so that the pressing action causes activation of a corresponding switch 33a, 33b. The switch generates a signal to the controller 5. The controller uses the mapping 40 to identify a memory location where there are stored computer instructions 41 corresponding to the selected destination mark 26.

The controller 5 then automatically processes the computer instructions 41. In this case, the computer instructions include a script in the form of a sequence of instructions that, when run by the controller 5, causes the controller 5 to initiate wireless communication between the interface device 1 and an access device associated with the destination mark. The controller 5 interprets the sequence, reads the selected data item 2, and causes the interface device 1 to transmit the data item 2 to printer apparatus in accordance with IrDA (Infra red Data Association) communication protocol requirements using the IR (infra red) transmitter module 9.

The printer apparatus is capable of receiving the IR wireless transmission from the interface device, running an e-mail client, and transmitting e-mail over a communications network. Clearly, the computer instructions 41 could address any suitable alternative access device that is capable of carrying out these functions. For example, the access device could alternatively be a PC or notebook computer, a set top box, refrigerator, or any other suitable electronic device.

The script also contains instructions for causing the interface device 1 to: transmit the data item 2 together with any other presently selected data item to the access device in appropriate format; inform the access device of the desired e-mail address; and cause the access device to send the selected data item(s) 2 to the desired e-mail address. Many alternative use models will be apparent to the skilled reader. For example, the destination mark 26 may be pressed once, before the record mark 23, to initialize the access device, to open a communications channel with printer apparatus and cause the apparatus to run its e-mail client. Data items can then be selected and transmitted sequentially responsive to each press of a record mark 23. As a further alternative example, one press of a record mark 23 could cause selection of a data item 2, and a second press of the record mark 23 in rapid succession to the first could initiate the transmission steps.

Alternatively or additionally, the user decides that he wishes to print the image selected as described above. The user presses the “printer” destination mark 29. This causes the interface device 1 to access and run corresponding computer instructions 41, in a similar process to that described above in connection with activation of the e-mail destination mark 26. The corresponding script causes the interface device 1 to initiate communication with and initialise, for printing, the selected printer apparatus, for example, a local printer in the user's home. The script also causes the interface device 1 to transmit the presently selected image to the printer apparatus in appropriate format together with instructions to effect printing.

Pressing “TV” destination mark 28 causes the interface device 1 to access and run corresponding computer instructions 41, in a similar process to that described above in connection with activation of the destination marks 26 and 29. The corresponding script causes the interface device 1 to transmit the presently selected image to a set-top box processor connected to television apparatus, or to television apparatus integrally provided with a suitable digital processor and remote communications device. The image is transmitted in appropriate format together with instructions to cause the television apparatus to display the image.

Many other possible combinations of destinations and predetermined controller responses will be apparent to the skilled reader. It will further be apparent that the embodiments of the interface device 1 described above enable a range of particularly convenient use models to be offered to users of stored data items.

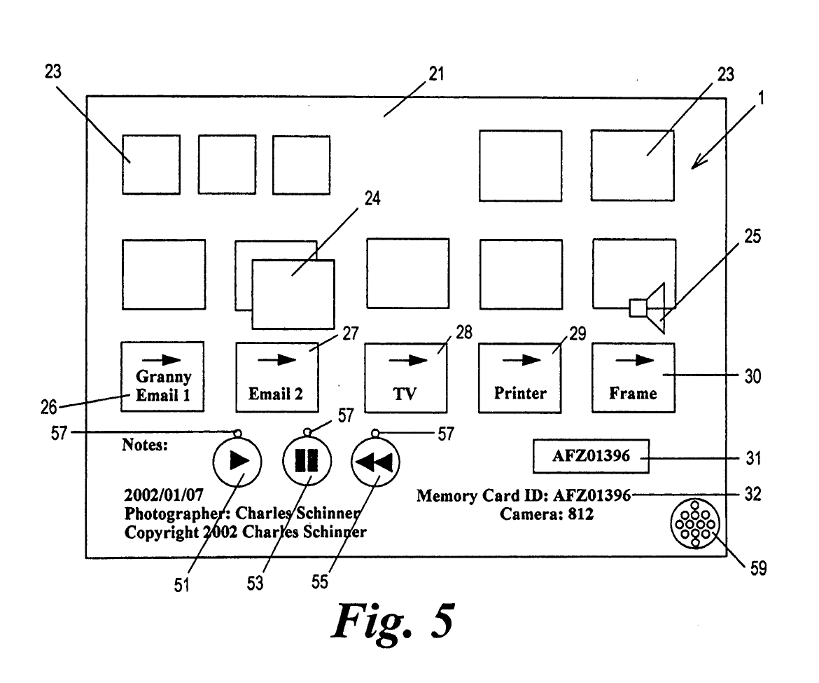

FIG. 5 shows a further embodiment of the interface device 1, modified to include additional features. Like reference numerals are used to designate features already described above with reference to FIGS. 1 to 3. To avoid unnecessary repetition, such features are not described again in detail. Control marks 51, 53 and 55 are provided in alignment with respective further switch actuating regions (not shown) for activating further switches (not shown). The further switches and their activating regions are similar to the switches 33a, 33b and actuating regions 35 described above in connection with FIGS. 1 to 3.

Actuation of one of the further switches causes the controller 5 to locate and access corresponding further computer instructions 41 using the mapping 40. The computer instructions 41 are executed by the controller 5 to provide appropriate control signals for controlling control functions of a presently selected access device or other electronic device. The computer instructions are arranged to cause the transceiver 9 to transmit the control signals to the selected device. For example, where the device is printer apparatus, the control marks 51, 53, 55 could be respectively operable to print the next image selected using the interface device 1, pause printing and move through a sequence of images for selecting a desired image. In a further alternative, the control marks 51, 53, 55 could be operable to remotely control the functions of a home audio system or other electronic equipment. For example, where the device is a compact disc player, the control marks 51, 53 and 55 could be operable to respectively play, replay and pause audio data accessed from a compact disc by the compact disc player, and/or to adjust playing characteristics such as volume.

Light emitting diodes (LEDs) 57 are provided that are arranged to light up when switches corresponding to the control marks 51 to 55 are in the actuated condition. A loudspeaker 59 is also provided. One function of the LEDs 57 and the loudspeaker 59 is to provide feedback to a user during actuation of the interface device 1, to facilitate accurate user control of the device 1. The speaker 59 can also be employed, for example, for playing audio clips to facilitate selection of a stored record.

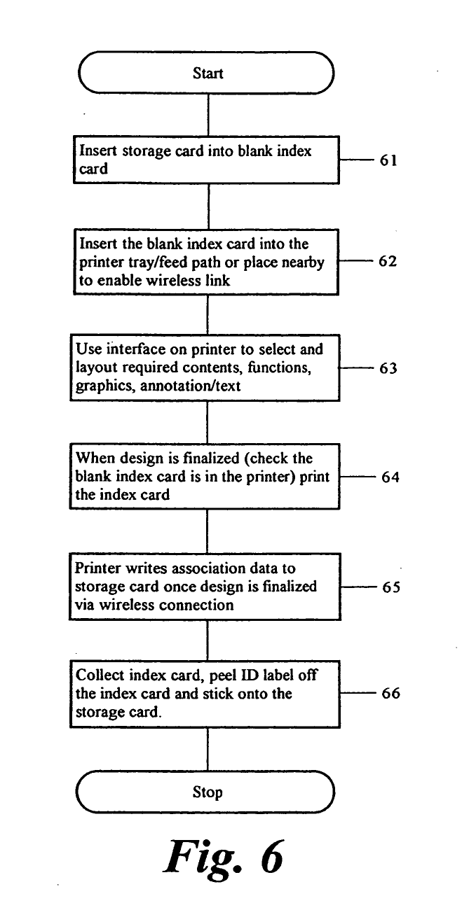

Referring to FIGS. 6 to 8, an interface blank 1a has the features of the interface device 1 described with reference to FIGS. 1 and 2, with the exception of the printed marks and the inserted memory card. The body 54 of the blank 1a has a substantially sheet-like form to facilitate passage through a commonly available printing mechanism. The blank body 54 is substantially rigid. Alternatively, the blank body 54 is flexible. A printable surface portion 21 of the blank 1a, including the actuating regions 35, is capable of being printed on using conventional printing technology, for example, ink jet or any other suitable printing technology.

A printer apparatus 45 is equipped with ink jet printing technology and a transceiver 47 for wireless RF communication. The printer apparatus 45 includes a printing mechanism (not shown) that can accommodate the blank 1a. It is envisaged that a standard printing mechanism of commonly available type will be suitable for accommodating the blank 1a, with or without a substantially rigid memory card inserted therein. However, an alternative specially adapted printing mechanism can be provided if required for accommodating any desired form of blank, for example, a flexible or a rigid blank, with or without a desired size of memory card inserted therein.

The printer apparatus 45 also includes an electronic processor (not shown) and non-volatile memory (not shown), and has a specially adapted customization interface 49 for enabling a user to produce an interface device having a desired arrangement of printed marks 23 to 30. The customization interface 49 includes software stored in the non-volatile memory of the printer apparatus 45, user operable controls, in the form of buttons, for controlling operation of the software, and a display in the form of an LCD display panel 50.

A process will now be described for arranging the marks 23 to 30 and disposing the printed marks 23 to 30 on the interface device 1, and for logically associating the marks 23 to 30 with corresponding data items 2 and computer instructions 41.

FIG. 6 illustrates a method of producing a customized interface device 1. A memory card 3, on which records in the form of photographic images are stored as data items 2, is inserted into the pocket 13 of the blank 1a (step 61). The blank 1a is placed close enough to the printer apparatus 45 to enable wireless communication between the blank 1a and the printer apparatus 45, for example, in a feed tray 52 of the printer apparatus 45 (step 62). The user initializes the customization interface 49. In response to initialization, or to activation of specific control buttons by the user, the interface 49 communicates with the memory card 3 and causes data comprising the data items 2 on the memory card to be transmitted to the transceiver 47 for temporary storage and processing by the printer apparatus 45.

Using suitable control means provided by the customization interface 49, the user is able to select and arrange marks on the display panel 50 for printing onto the blank device 1a, and delete marks relating to data items that do not have to be printed (step 63). The customization interface 49 may enable editing of marks and/or provide a range of previously prepared marks for selection. For example, the user may select the size and/or color of marks, add notes or comments to a mark or group of marks, add audio clip commentary or delete audio content, and make use of graphics tools provided by the customization interface 49.

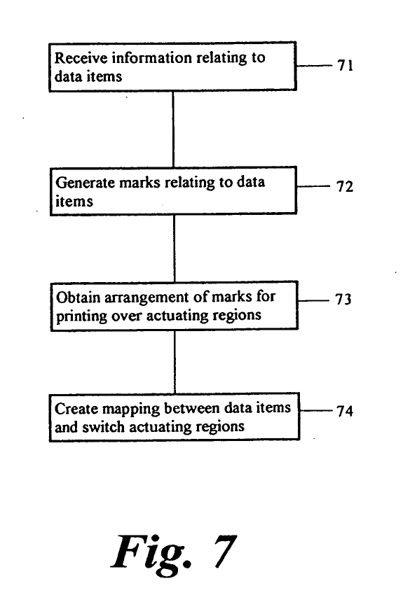

FIG. 7 illustrates a method carried out by the processor of the printer apparatus 45 in accordance with instructions stored in the non-volatile memory of the printer apparatus 45. Following receipt of the data items 2 (step 71) from the memory card 3, the customization interface 49 generates a mark for each data item 2 (step 72) and displays the marks on the display panel 50. The marks take the form of thumbnails of the stored images, and are generated using data portions in the form of data files created by the printer apparatus 45 using the received data items 2. Alternatively, the marks could be filenames, images not derived directly from the data items 2 but selected by the user from selection provided by the customization interface 49, names inputted to the customization interface 49 by the user, or any other conveniently recognizable representation of a data item 2.

Before printing the marks 23 to 25 onto the blank device 1a, the printer apparatus 45 arranges each mark (step 73) such that, when printed on the blank device 1a, the mark will be in alignment with at least one switch actuating region 35. The printer apparatus carries out this final arrangement automatically, taking into account any desired arrangement input by the user. The arranging activity is also carried out during the customization process, so that the customization interface 49 can inform the user when a desired arrangement is not practicable.

Information about the disposition of the switch actuating regions 35 on the blank device 1a is necessary to arrange the marks 23 to 25 relative to the actuating regions 35. For a commonly used standard blank device 1a, this information is prestored in the non-volatile memory of the printer apparatus 45. Alternatively, the information is obtained from another memory source such as a CD-ROM, or obtained over the Internet. As a further alternative, the information is stored in memory on the interface blank 1a and wirelessly communicated to the printer device 45.

The printer apparatus also creates the mapping 40 (step 74), in the form of a file containing logical associations linking a storage location of each data item 2 on the interface device 1 with the actuating region or regions 35 to be overprinted by the mark 23 to 25 corresponding to that data item 2.

The customization interface 49 is also used to implement the destination marks 26 to 30. The customization interface 49 is operable to enable the user to select from a prestored selection of destination devices, and/or to enable the user to input details of a destination device not available for selection. For example, the customization interface 49 may display a menu of printer, display and/or communication devices, or other type of digital device, optionally including the make and/or model of each device. The customization interface 49 also displays a menu of applications programs for use with a selected destination device, for example, e-mail clients and web browsers.

Selection of a destination device causes the customization interface 49 to generate a destination mark 26 to 30 using a data portion stored by the printer apparatus 45 in connection with the selected destination device. Subsequently, the customization interface 49 arranges the destination mark 28, 29 for printing in similar manner to the arrangement of the record marks 23 to 25 described above.

The act of selection also causes the printer device 45 to prepare for transmission, for storage on the memory card 3, blank device 1a (if adequate memory is provided thereon) or elsewhere, any computer instructions 41 that might be necessary for enabling the interface device 1 to correctly format and transmit data items 2 to the selected destination device, or to identify what application software is available to a selected destination device. However, at least some of the computer instructions 41 may be already carried by the interface device 1, for example, in the controller 5 or wireless module 9, and therefore will not need to be transmitted by the printer device 45 to the interface device 1.

The computer instructions 41 comprise, for example, application related and/or communications protocol related software, and/or the script for initiating communication between the interface device 1 and an access device. At least some of the computer instructions 41 can be prestored in the non-volatile memory of the printer apparatus 45, obtained from another memory source such as a CD-ROM, obtained over the Internet, or obtained in any other convenient manner.

The customization interface 49 enables the user to add personalized data to the computer instructions 41, for example, e-mail address details for enabling automatic sending of a selected data item to a desired address by an e-mail client running on a destination communications device.

The control marks 51, 53, 55 can also be selected using a menu provided by the customization interface 49. The customization interface 49 is operable to enable the user to select from a prestored list of control marks, which list also notes, for each mark, corresponding devices that the mark is suitable to control. Selection of a control mark causes the customization interface 49 to generate a control mark 51, 53, 55 using a data portion stored by the printer apparatus 45. Subsequently, the customization interface 49 arranges the control mark 51, 53, 55 for printing in similar manner to the arrangement of the record and destination marks 23 to 30 described above.

The act of selection further causes the printer device 45 to prepare for transmission, for storage on the memory card 3, blank device 1a or elsewhere, further computer instructions 41. The further computer instructions 41 are for enabling the interface device 1, in response to actuation of selected control marks 51, 53, 55, to generate control signals for controlling a corresponding electronic device that the user wishes to control. The further computer instructions 41 include a script (sequence of instructions) for automatically initiating transmission of the control signals from the interface device 1 to the controlled device. However, at least some of the further computer instructions 41 may be already carried by the interface device 1 and therefore will not need to be transmitted by the printer device 45 to the interface device 1. At least some of the computer instructions 41 can be prestored in the non-volatile memory of the printer apparatus 45, obtained from another memory source such as a CD-ROM, obtained over the Internet, or obtained in any other convenient manner.

The printer apparatus 45 also includes in the mapping 40, or a separate mapping, logical associations linking i) a storage location of each set of computer instructions 41 on the interface device 1 with ii) the actuating region or regions 35 to be overprinted by the destination or control mark 26 to 30, 51, 53, 55 which corresponds to that set of computer instructions 41. The computer instructions' storage location on the interface device 1 can be determined by the printer apparatus 45 and communicated to the interface device 1 during transmission of the computer instructions 41 to the interface device 1. Alternatively, the mapping 40 can be created during storage of the instructions 41, the storage location being selected by the interface device controller 5.

The control marks 51, 53, 55 and LEDs 57 are alternatively preformed on the interface device blank 1a, and the further corresponding computer instructions 41 are in a mapping prestored on the blank 1a.

Referring again to FIG. 6, the user confirms that the arrangement of marks is satisfactory, and the printer apparatus 35 prints the destination marks 26 to 30 and the control marks 51, 53, 55 in alignment with the actuating regions in accordance with the arrangement (step 64). Also, the printer apparatus 35, using the transceiver 47 and wireless module 9, transmits the mapping 40 to the blank 1a, for storage on the blank 1a or the memory card 3 as appropriate (step 65). The self-adhesive label 31 is transferred from the face of the interface blank to the location on the memory card 3 provided therefore (step 66).

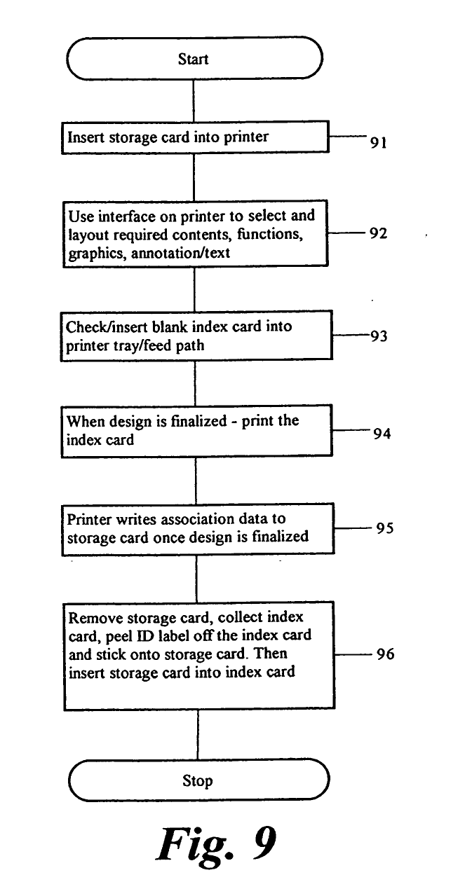

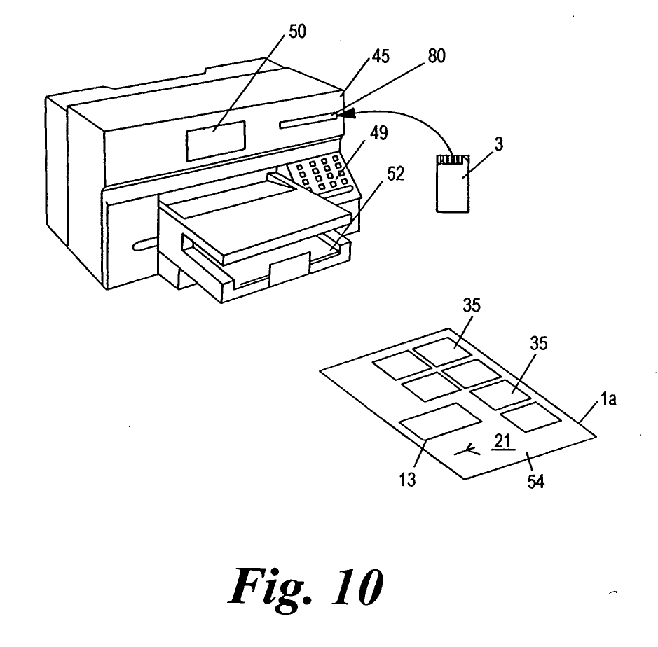

FIGS. 9 and 10 illustrate a modified method of producing a customized interface device 1. Like reference numerals will used to designate features already described above with reference to FIGS. 6 to 8. To avoid unnecessary repetition, such features are not described again in detail.

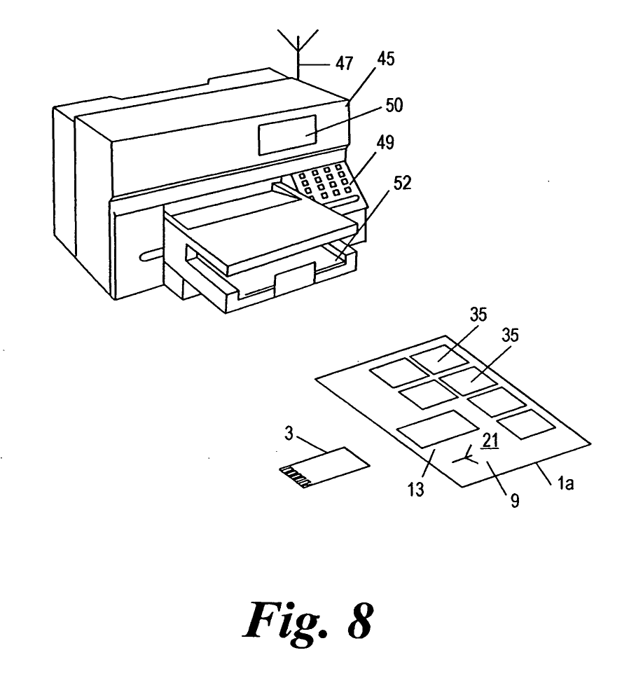

The interface device blank 1a shown in FIG. 10 is similar to that shown in FIG. 8. The printer apparatus 45a is modified to include a memory card reader/writer 80. The memory card 3 is inserted in the memory card reader/writer 80 (step 91). This facilitates faster and more efficient communication between the printer apparatus 45a and the memory card 3 compared to wireless communication, particularly for large data items 2, such as those relating to large still image or video records.

The customization interface 49 is used as described above with reference to FIGS. 6 to 8, to select and finalize arrangement of the desired record, destination and control marks 23 to 30, 51, 53, 55 (step 92). The blank 1a is placed in the feed path of the printer apparatus 45 (step 93). The arrangement of marks is printed onto the blank 1a (step 94). The printer apparatus 45 creates and transmits the mapping 40 to the memory card 3 (step 95). The memory card 3 is removed from the reader/writer 80 and inserted in the pocket 13. The label 31 is affixed to the memory card 3.

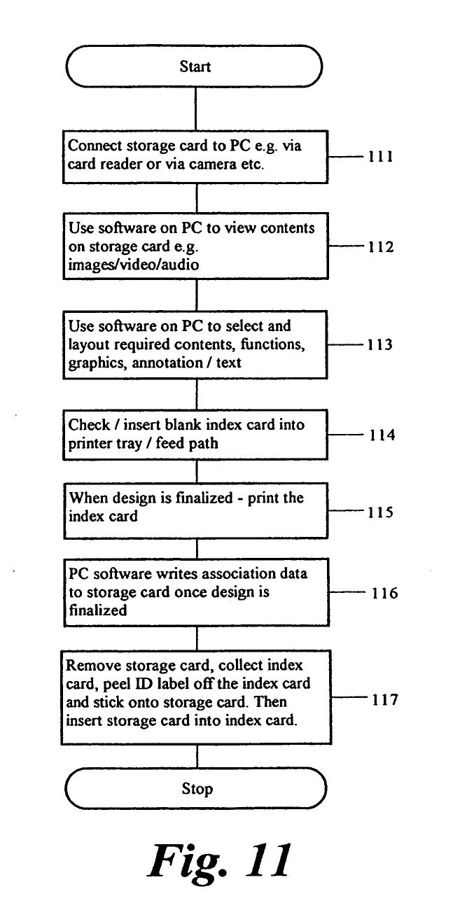

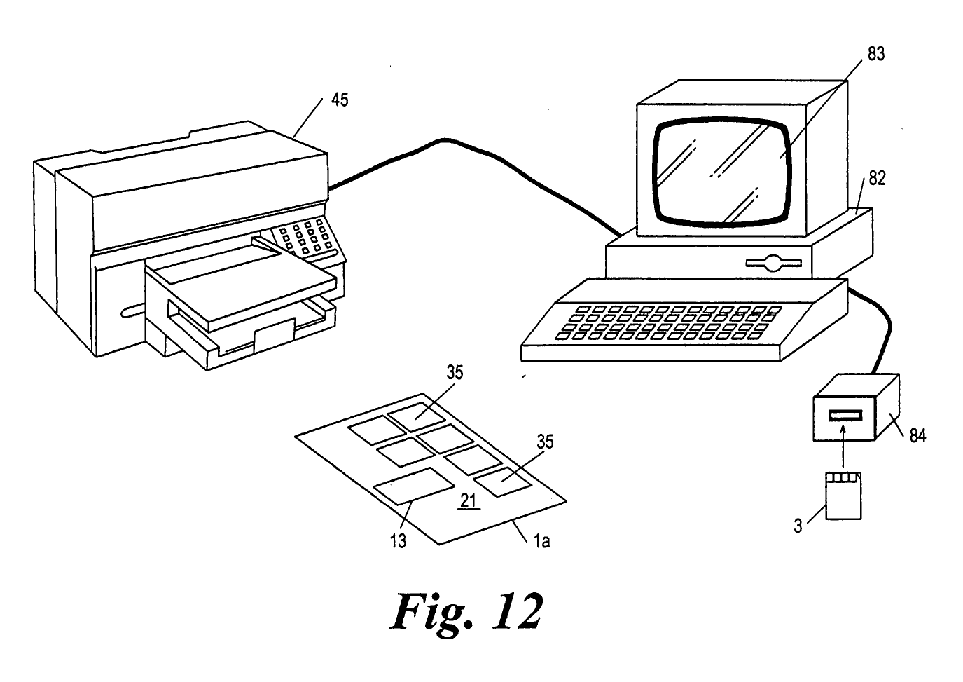

FIGS. 11 and 12 illustrate a further modified method of producing a customized interface device 1. Like reference signs will used to designate features already described above with reference to FIGS. 6 to 8. To avoid unnecessary repetition such features are not described again in detail.

The interface device blank 1a shown in FIG. 12 is similar to that shown in FIG. 8. The printer apparatus 45 does not include the customization interface 49 or display 50. Instead, the printer apparatus is connected for data communications with a personal computer (PC) 82 operable to execute software so as to provide the customization interface functionality described with reference to FIGS. 6 to 8. The PC 82 is connected to a display 83, a user input interface in the form of a keyboard 84, and a memory card reader/writer 84.

The memory card 3 is inserted in the memory card reader/writer 84. Alternatively, a camera loaded with a memory card 3 is connected to the PC 82 (step 111). The PC 82 is used to view the contents of the memory card 3 (step 112). The desired record, destination and control marks 23 to 30, 51, 53, 55 are selected and finalised using the customization interface (step 113). The blank 1a is placed in the feed path of the printer apparatus 45 (step 114), the arrangement of marks is printed onto the blank 1a (step 15), the processor of the PC carries creates the mapping 40, and the PC 82 transmits the mapping 40 to the memory card 3 using the reader/writer 84 (step 116). The memory card 3 is then inserted in the pocket 13 and the label 31 is affixed to the memory card 3.

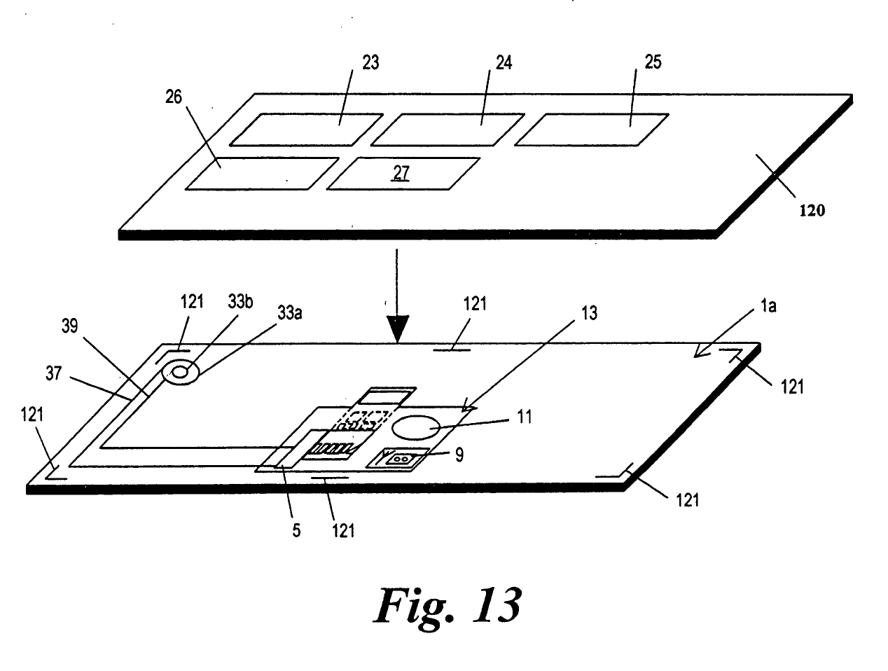

In a modification of the processes described above, a separate overlay sheet 120 of printable material, shown in FIG. 13, is fed instead of the blank 1a into the printer apparatus 45 and printed with the arrangement of marks 23 to 30, 51, 53, 55. The blank 1a is provided with alignment markings 121 for correctly aligning the printed overlay 120 and the blank 1a such that the marks assume a predetermined disposition relative to the actuating regions 35 of the blank 1a. In this manner, the blank does not have to pass through a printer mechanism, so that special adaptations of the blank 1a or printer mechanism are not necessary. Furthermore, the blank 1a need not be provided with a printable surface portion.

In a further modified process, the printer apparatus 45 automatically generates and arranges the marks, with minimal or no user customization input. For example, an interface device blank has a preformed standard arrangement of paths 37, 39 and disposition of actuating regions. A standard mapping 40 of actuation regions 35 to storage locations on a predetermined type of memory card 3 is pre-stored on the blank. Thus, when the blank is connected to a memory card 3, data items 2 stored on the memory card 3 are associated in the mapping 40 with respective actuating regions 35. The data items 2 are matched sequentially, in the order in which the data items 2 appear in the storage locations on the memory card 3, with the actuating regions 35 in the order in which the regions 35 appear on the interface device 1, for example, left to right and top to bottom row.

The various blanks 1a discussed above can be constructed many convenient forms, which will be readily apparent to the skilled reader. For example, the blank 1a shown in FIG. 13 for use with the overlay 120 takes the form of a printed circuit board (PCB) having a body of reinforced or unreinforced resin, paths 37, 39 in the form of copper tracks, a controller 5 and module 9 comprising integrated circuits fabricated in a generally known manner, and switches 33a, 33b that are etched. The switches 33a, 33b are alternatively provided in a separate operation by attaching pairs of preformed electrically conductive contacts 33a, 33b to the PCB.

To form a directly printable blank 1a, a PCB similar to that shown in FIG. 13 is provided, except that only one contact 33a of each switch 33a, 33b is attached to the PCB. A layer of printable material (not shown) is then laid over the PCB. The printable layer has contacts 33b on its inwardly directed face that are aligned with the contacts 33a of the PCB, such that the aligned pairs of contacts 33a, 33b form switches.

In a still further alternative, the material of the body of the blank 1a is directly printable, such that the marks 23 to 30, 51, 53, 55 can be applied thereto by passing the blank 1a through a printer mechanism. Still further, the paths 37, 39 and circuits for providing various elements of the interface device 1, for example, for providing the switches 33a, 33b, controller 5, module 9, battery 11, may be applied to the body of the blank 1a by directly printing conductive material onto the body.

Particularly where flexibility is required, blanks 1a can be fabricated, for example, using a synthetic material such as polyamide or other plastics material, or using paper. Suitable further alternative body materials will be apparent to the skilled reader.

1-38. (canceled)

39. An apparatus adapted to produce a user interface device for use in accessing records stored as data items in an electronic storage device, the apparatus comprising:
a receiver adapted to receive data items from the storage device;
a mark generator adapted to generate marks corresponding to said data items;
an arranger adapted to arrange said marks for printing; and
a file generator adapted to use information about a disposition of switch actuating regions on the interface device to generate an association file that associates each data item with at least one actuating region that, according to the arrangement of marks, is aligned with a said mark corresponding to said data item.

40. The apparatus as claimed in claim 39, wherein said file generator is further adapted to generate an association file for associating at least one further switch actuating region with program instructions for controlling at least one of a control function of the interface device or a control function of a user access device.

41. The apparatus as claimed in claim 39, wherein said arranger is further adapted to arrange selected control marks in alignment with said further switch actuating regions.

42. The apparatus as claimed in claim 39, further comprising a customization interface adapted to enable a user to determine the arrangement of said marks.

43. The apparatus as claimed in claim 39, further comprising a customization interface adapted to enable a user to select which stored data items are to be marked on the user interface device.

44. (canceled)

45. (canceled)

46. A method of manufacturing an interface device having an arrangement of switch actuating regions adapted to transmit data items stored on a memory device to a remote device, the method comprising:
receiving information about data items stored on the memory device, generating marks respectively relating to said data items in accordance with said information;
arranging said marks in a desired arrangement with a customization interface;
creating an association file to associate each data item relating to a mark with at least one said switch actuating region;
writing said association file to a memory to accompany said interface device; and
printing said marks in said arrangement onto a surface such that each mark is one of either aligned or alignable with an associated switch actuating region.

47. The method as claimed in claim 46, wherein said non-volatile memory comprises said memory device.

48. The method as claimed in claim 46, further comprising printing the marks directly onto said interface device.
